(19) United States
(12) Patent Application Publication
(10) Pub. No.: US 2025/0318328 A1
(43) Pub. Date: Oct. 9, 2025

(54) LAMP BEAD STRUCTURE

(71) Applicant: Ji'an Mulinsen Components Co., Ltd., Ji'an (CN)

(72) Inventors: Caixiang ZHOU, Ji'an (CN); Lijun LIU, Ji'an (CN); Meizhong XIONG, Ji'an (CN); Wenxin HUANG, Ji'an (CN); Nana ZOU, Ji'an (CN)

(73) Assignee: Ji'an Mulinsen Components Co., Ltd., Ji'an (CN)

(21) Appl. No.: 19/242,920

(22) Filed: Jun. 18, 2025

(30) Foreign Application Priority Data
Feb. 24, 2025 (CN) 202520288954.0

(51) Int. Cl. H10H 20/85

(52) U.S. Cl. CPC H10H 20/8502; H10H 20/8504

(57) ABSTRACT

The present disclosure provides a lamp bead structure, comprising a bracket, a light-emitting chip and a packaging member are on the bracket, the light-emitting chip is mounted on the bracket. The bracket includes a first metal plate and a second metal plate, and there is a mounting gap between the first and second metal plates. One end of the packaging member is connected to the first metal plate, the other end passes through the packaging member to connect with the second metal plate, and the packaging member is connected to the light-emitting chip. The light emitted by the light-emitting chip will diffuse at the packaging member to achieve 3600 luminescence, avoiding the problem that the light of the light-emitting chip can only emit forward with no light at the back side, thereby enabling the lamp bead structure to better adapt to various application scenarios and enhancing its utilization ratio.

### RELATED APPLICATIONS

The present patent document claims the benefit of priority to patent application No. 202520288954.0, filed Feb. 24, 2025, and entitled “LAMP BEAD STRUCTURE,” the entire contents of each of which are incorporated herein by reference.

### BACKGROUND

### 1. Technical Field

The present disclosure relates to the technical field of lamp beads, and in particular to a lamp bead structure.

### 2. Background Information

LED lamp beads are now widely used in various applications. However, Most of the LED lamp beads currently used emit light only from front sides, while bottoms of brackets do not emit light, resulting in luminous blind areas of the lamp beads, which limits the application scenarios of lamp bead structures and leads to low utilization ratio of the lamp beads.

### BRIEF SUMMARY

The present disclosure solves one of the problems existing in the prior art to a certain extent. For this reason, one of the objectives of the present disclosure is to provides a lamp bead structure that achieves 3600 luminescence.

The above objective is achieved through the following technical solution.

A lamp bead structure comprises a bracket, wherein a light-emitting chip and a packaging member are on the bracket, and the light-emitting chip is mounted on the bracket. The bracket includes a first metal plate and a second metal plate, and there is a mounting gap between the first metal plate and the second metal plate. One end of the packaging member is connected to the first metal plate, the other end passes through the mounting gap to connect with the second metal plate, and the packaging member is connected to the light-emitting chip.

As a further improvement of the present disclosure, the packaging member includes an epoxy resin or a silicone resin.

As a further improvement of the present disclosure, a first avoiding position is formed on the first metal plate, and a second avoiding position is formed on the second metal plate. When the packaging member connects the first metal plate and the second metal plate, the packaging member fills the first avoiding position and the second avoiding position.

As a further improvement of the present disclosure, the first metal plate includes a first main body and a first extension piece extending from the first main body toward the second metal plate, and a width of the first extension piece is smaller than that of the first main body.

As a further improvement of the present disclosure, the first avoiding position is formed on the first extension piece near the first main body.

As a further improvement of the present disclosure, the second metal plate includes a second main body and a second extension piece extending from the second main body toward the second metal plate, and a width of the second extension piece is smaller than that of the second main body.

As a further improvement of the present disclosure, the second avoiding position is formed on the second extension piece near the second main body.

As a further improvement of the present disclosure, a transverse rib is provided between adjacent brackets.

As a further improvement of the present disclosure, a transverse rib is provided between the adjacent brackets.

Compared with the prior art, the present disclosure has at least the following beneficial effects:

1. The present disclosure provides a lamp bead structure, one end of the packaging member is connected to the first metal plate, the other end passes through the mounting gap to connect with the second metal plate, and the packaging member is connected to the light-emitting chip. The light emitted by the light-emitting chip will diffuse at the packaging member to achieve 3600 luminescence, avoiding the problem that the light of the light-emitting chip can only emit forward with no light at the back side, thereby enabling the lamp bead structure to better adapt to various application scenarios and enhancing the utilization ratio of the lamp bead structure.

### BRIEF DESCRIPTION OF THE DRAWINGS

FIG. 1 is a structural schematic view of a bracket according to an embodiment.

FIG. 2 is another structural schematic view of the bracket according to the embodiment.

FIG. 3 is a structural schematic view of a lamp bead structure according to an embodiment.

FIG. 4 is another structural schematic view of the lamp bead structure according to the embodiment.

FIG. 5 is structural schematic view of multiple brackets connected according to the embodiment.

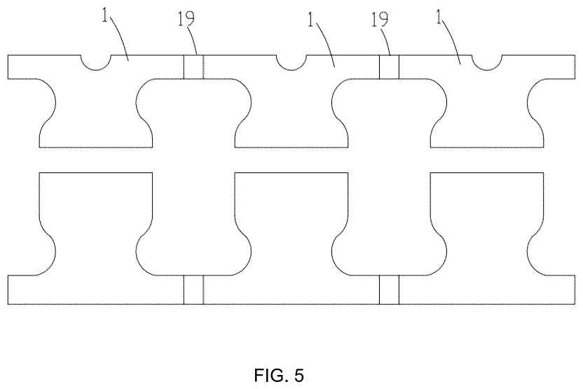

### DETAILED DESCRIPTION OF THE DRAWINGS AND THE PRESENTLY PREFERRED EMBODIMENTS

The present disclosure is illustrated by the following embodiments, but the present disclosure is not limited to these embodiments. Modifications to the specific implementations of the present disclosure or equivalent replacements of some technical features, made without departing from the spirits of the utility disclosure, shall all fall within the scope of the technical solutions claimed by the utility disclosure.

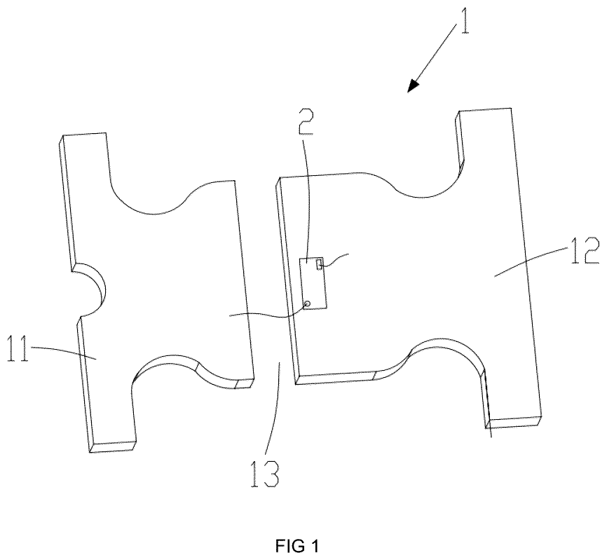

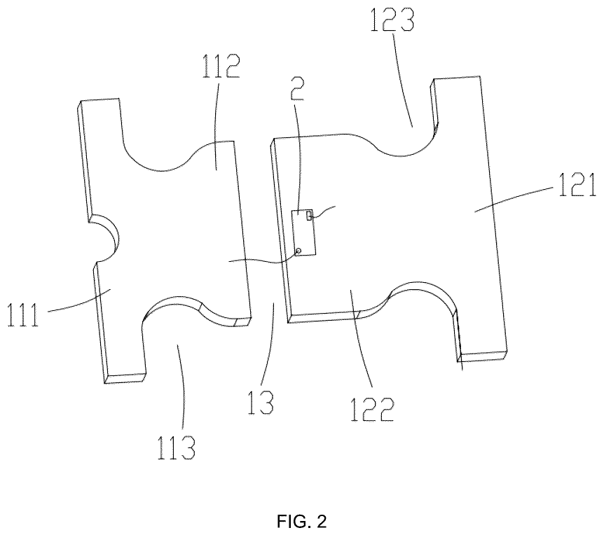

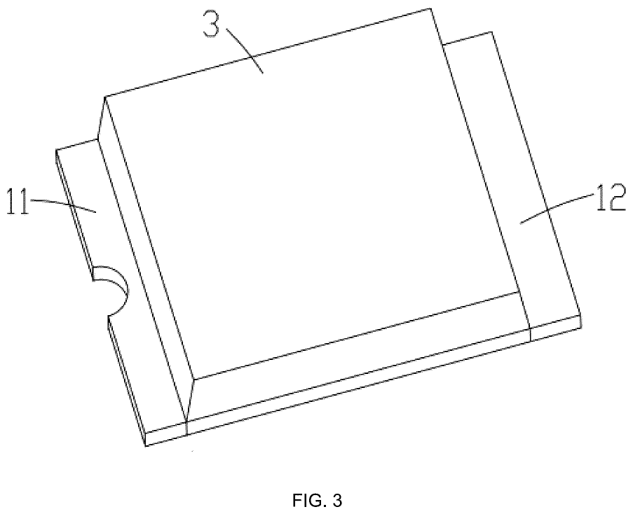

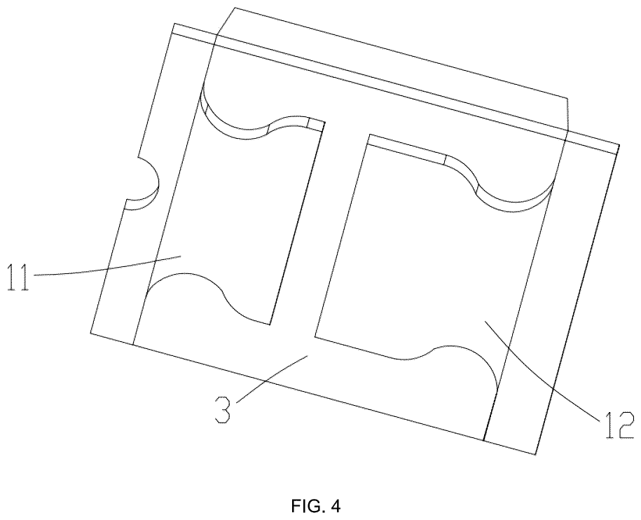

As shown in FIGS. 1 to 4, a lamp bead structure comprises a bracket 1, wherein a light-emitting chip 2 and a packaging member 3 are on the bracket 1, and the light-emitting chip 2 is mounted on the bracket 1. The bracket 1 includes a first metal plate 11 and a second metal plate 12, and there is a mounting gap 13 between the first metal plate 11 and the second metal plate 12. One end of the packaging member 3 is connected to the first metal plate 11, the other end passes through the mounting gap 13 to connect with the second metal plate 12, and the packaging member 3 is connected to the light-emitting chip 2.

The present disclosure provides a lamp bead structure, the bracket 1 retains only metal plates, and a mounting gap 13 is formed between the first metal plate 11 and the second metal plate 12. The first metal plate 11 is connected with the second metal plate 12 through the packaging member 3, and a position between the first metal plate 11 and the second metal plate 12 is relatively fixed.

One end of the packaging member 3 is connected to the first metal plate 11, the other end passes through the mounting gap 13 to connect with the second metal plate 12, and the packaging member 3 is connected to the light-emitting chip 2.

The light-emitting chip 2 is mounted on the bracket 1, that is, the light-emitting chip 2 is mounted on the first metal plate 11 or the second metal plate 12. When the packaging member 3 connects the first metal plate 11 or the second metal plate 12, the packaging member 3 will also come into contact with the light-emitting chip 2.

The light-emitting chip 2 will emit light, and the light emitted by the light-emitting chip 2 will diffuse at the packaging member 3 to achieve 3600 luminescence, avoiding the problem that the light of the light-emitting chip 2 can only emit forward with no light at the back side, thereby enabling the lamp bead structure to better adapt to various application scenarios and enhancing the utilization ratio of the lamp bead structure.

In this embodiment, the packaging member 3 is made of an epoxy resin, or the packaging member 3 is made of a silicone resin.

In this embodiment, the light-emitting chip 2 is mounted on the second metal plate 12.

In this embodiment, the light-emitting chip 2 is mounted at a front-side position of the second metal plate 12.

In some embodiments, a first avoiding position 113 is formed on the first metal plate 11, and a second avoiding position 123 is formed on the second metal plate 12. When the packaging member 3 connects the first metal plate 11 and the second metal plate 12, the packaging member 3 fills the first avoiding position 113 and the second avoiding position 123. When the packaging member 3 fills the first avoiding position 113 of the first metal plate 11 and the second avoiding position 123 of the second metal plate 12, the light emitted by the light-emitting chip 2 will diffuse at the packaging member 3, so that more light can emit from the backside of the bracket 1.

In this embodiment, the first metal plate 11 includes a first main body 111 and a first extension piece 112 extending from the first main body 111 toward the second metal plate 12, and a width of the first extension piece 112 is smaller than that of the first main body 111.

The first avoiding position 113 is formed on the first extension piece 112 near the first main body 111.

In this embodiment, the second metal plate 12 includes a second main body 121 and a second extension piece 122 extending from the second main body 121 toward the first metal plate 11, and a width of the second extension piece 122 is smaller than that of the second main body 121.

The second avoiding position 123 is formed on the second extension piece 122 near the second main body 121.

A transverse rib 19 is provided between adjacent brackets 1. Since the bracket 1 retains only the metal plates, the transverse rib 19 is added between the two brackets 1 to reinforce the strength of the brackets 1.

The above preferred implementations shall be regarded as illustrative examples of the implementation of the present disclosure. Any technical deductions, substitutions, improvements, or similar implementations that are substantially identical to, approximate to, or based on the solutions of the present disclosure shall all fall within the protection scope of this patent.

1. A lamp bead structure, comprising a bracket, wherein a light-emitting chip and a packaging member are on the bracket, the light-emitting chip is mounted on the bracket; the bracket includes a first metal plate and a second metal plate, and there is a mounting gap between the first metal plate and the second metal plate;
one end of the packaging member is connected to the first metal plate, the other end passes through the mounting gap to connect with the second metal plate, and the packaging member is connected to the light-emitting chip.

2. The lamp bead structure according to claim 1, wherein the packaging member includes an epoxy resin or a silicone resin.

3. The lamp bead structure according to claim 1, wherein a first avoiding position is formed on the first metal plate, and a second avoiding position is formed on the second metal plate; when the packaging member connects both the first metal plate and the second metal plate, the packaging member fills the first avoiding position and the second avoiding position.

4. The lamp bead structure according to claim 3, wherein the first metal plate includes a first main body and a first extension piece extending from the first main body toward the second metal plate, and a width of the first extension piece is smaller than that of the first main body.

5. The lamp bead structure according to claim 4, wherein the first avoiding position is formed on the first extension piece near the first main body.

6. The lamp bead structure according to claim 3, wherein the second metal plate includes a second main body and a second extension piece extending from the second main body toward the first metal plate, and a width of the second extension piece is smaller than that of the second main body.

7. The lamp bead structure according to claim 6, wherein the second avoiding position is formed on the second extension piece near the second main body.

8. The lamp bead structure according to claim 1, wherein a transverse rib is provided between adjacent brackets.
